(19) United States
(12) Patent Application Publication
(10) Pub. No.: US 2007/0227877 A1
(43) Pub. Date: Oct. 4, 2007

(54) Magnetron-sputtering film-forming apparatus and manufacturing method for a semiconductor device

(75) Inventor: Wensheng Wang, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/495,670

(22) Filed: Jul. 31, 2006

(30) Foreign Application Priority Data
Mar. 28, 2006 (JP) 2006-087957

(51) Int. Cl. C23C 14/32; C23C 14/00

(52) U.S. Cl. 204/192.1; 204/298.02

(57) ABSTRACT

A magnetron-sputtering film-forming apparatus includes: a vacuum film-forming chamber (11); electrostatic chuck units (12) for adjusting a temperature of the substrate (14); a target (15) for causing high-frequency magnetron sputtering; power supply units (17) for applying a discharge voltage between the substrate (14) and the target (15), and calculating an integral power consumption of an electricity discharged by the target (15); and control units (18) for controlling the electrostatic chuck units (12) and the power supply units (17). In the magnetron-sputtering film-forming apparatus, the temperature of the substrate to be processed (14) that is most suitable for sputtering is calculated based on the integral power consumption of the electricity discharged by the target (15) until that time, and the substrate (14) is adjusted to have a predetermined temperature to be subjected to the sputtering.

### BACKGROUND OF THE INVENTION

The present invention relates to a magnetron-sputtering film-forming apparatus, which is used for manufacturing a semiconductor device having a capacitor, and to a method of manufacturing a semiconductor device. In particular, the present invention is suitably applied to manufacture of a semiconductor device having a ferroelectric capacitor whose dielectric is composed of a ferroelectric film.

In recent years, with the developments in digital technologies, there is more demand for a high-speed processing or storage of large volumes of data. Thus, a high integration and a high performance of a semiconductor device used for electronic devices are required. In order to achieve a non-volatile RAM capable of writing and reading data with a low voltage and with a high speed, researches and developments are extensively carried out with regard to a ferroelectric random access memory (FeRAM) that uses a ferroelectric film whose capacitor insulating film has a spontaneous polarization characteristic.

The FeRAM stores information by utilizing a hysteresis characteristic of a ferroelectric substance. In the FeRAM, a ferroelectric capacitor, which includes a ferroelectric film as a capacitor dielectric film between a pair of electrodes, is provided for each memory cell. In the ferroelectric substance, a polarization occurs in accordance with an applied voltage between the electrodes. Even when the applied voltage is removed, a spontaneous polarization exists. Further, when a polarity of the applied voltage is reversed, a polarity of the spontaneous polarization is also reversed. Therefore, when the spontaneous polarization is detected, it is possible to read information of the FeRAM. The FeRAM is characterized in that a high-speed operation is possible, power consumption is low, a durability for writing/reading data is enhanced, and the like.

Similarly to a dynamic random access memory (DRAM), the FeRAM has a memory-cell structure composed of a switching transistor and a capacitor. As a dielectric layer of the capacitor, ferroelectric substances are used. As the ferroelectric substances, lead zirconate titanate (Pb (Zr, Ti) O₃) (commonly called “PZT”), for example, is used. The ferroelectric capacitor of the FeRAM is formed by depositing a lower electrode layer, a ferroelectric layer, an upper electrode layer in a multi-layer using, for example, a sputtering method. In this case, when the ferroelectric layer is formed, PZT is deposited, and then an annealing treatment is applied under a predetermined condition for crystallization of the ferroelectric substances which are in an amorphous state.

In general, in a sputtering film-forming apparatus, it is required that qualities of films formed on a substrate are uniform. For example, Patent document 1 proposes that, in order to reduce variation of film qualities (resistance ratio, relative proportion, impurity concentration, and the like) within a substrate, in accordance with a change in size of an erosion area of a target for sputtering, a sputtering power is increased when the erosion area is large, and a sputtering power is controlled to be decreased when the erosion area is small. Further, Patent document 2 proposes a device for carrying out sputtering by varying a distance between a surface of the target and a magnet to change a magnetic field. In addition, Patent document 3 and Patent document 4 proposes that an appropriate sputtering is performed by calculating an integrated available amount of a target with a total integral power consumption of a sputtering power, and by adjusting discharge voltage of a sputter discharge from a start of use of the target to an end of use thereof based on the calculated integral power consumption. Further, Patent document 5 proposes a technology for providing a pivoted magnetron magnetic circuit to a back surface of a target, reducing forming of nodules on a surface of the target, thereby eliminating the need to initialize the surface of the target and raising operation rates of an apparatus to enhance the productivity. Further, Patent document 6 proposes an apparatus for controlling a shutter opening/closing timing by using a target cell bias voltage. Furthermore, Patent document 7 proposes a technology for sputtering a plurality of targets to form a PZT film on a substrate. Patent document 8 proposes a technology for applying an RF voltage to a substrate to form a BaTiO₃ epitaxial-strained lattice film at the substrate DC bias potential of −5 to −30 V and at a substrate temperature of 350° C. or higher. Patent document 9 proposes a technology for forming an epitaxial-strained film by sputtering with predetermined conditions of a distance L between a target and a substrate, a sputter gas pressure P, and a target self-bias Vdc. Patent document 10 proposes a technology for correcting an ionization state of a plasma by a first power supply and a second power supply to achieve uniformity in thickness of a film to be formed and in depth of an erosion of the target. Further, Patent document 11 proposes a technology for rotating/revolving a substrate holder with respect to a target, thereby changing an incident angle and the like of sputtered atoms with respect to the surface of the substrate in a process of sputtering to uniformly form a film.

[Patent document 1] JP 05-263236 A

[Patent document 2] JP 05-132771 A

[Patent document 3] JP 2002-294444 A

[Patent document 4] JP 2001-158960 A

[Patent document 5] JP 2000-345335 A

[Patent document 6] JP 07-116602 B

[Patent document 7] JP 2688872 B

[Patent document 8] JP 2001-270795 A

[Patent document 9] JP 2001-189313 A

[Patent document 10] JP 3122421 B

[Patent document 11] JP 3526342 B

### SUMMARY OF THE INVENTION

A composition or a thickness of a ferroelectric film of a capacitor greatly affects an electrical property of the capacitor or a yield of an FeRAM device. As a result of an improvement of a sputtering film-forming apparatus, it has become possible in recent years to form a ferroelectric film having a uniform thickness and composition, irrespective of a development of erosion of a target. However, even at present when it is possible to form the ferroelectric film having the uniform thickness and composition thereof, in a case where the erosion of the target is in an extremely advanced stage during a process of sputtering, the yield of the FeRAM device is rapidly reduced. It should be noted that, in the sputtering target, the erosion area is enlarged in proportion to an increase of the integral power consumption of the discharged energy. FIG. 19 shows a measurement result of an erosion state of a target (thickness thereof before use is 5 mm) in a case where the integral power consumption of the discharged energy reaches 700 kWh. As shown in FIG. 19, the periphery or the center of the target is not largely sputtered, so a thickness of about 4 mm is maintained. On the other hand, in a portion in which a sputtering amount is large (concentrically), the erosion develops to a level at which the thickness thereof is reduced to 0.8 mm.

The erosion of the target has a profound effect on crystallinity of a ferroelectric film, a switching charge quantity of a capacitor, a leak current, deterioration in resistance process of the capacitor, and the yield of a device. The mechanism thereof is considered as described below. FIG. 20 shows an image of film formation within a sputtering chamber. In general, in sputtering, target materials are flicked off by kinetic energy of ions, so it is considered that a composition deviation of a compound is small as compared with a vacuum evaporation method which depends on an evaporation mechanism. Most of the sputtered particles are considered to be transported to a substrate in the form of a neutral atom. However, a part of the sputtered particles are ionized. In general, in a plasma region within a discharge space, a weak electric field, which extends from a peripheral portion toward a center portion, is formed. As a result, when the particles having electric charges pass through the electric field, a force toward the center portion acts. Accordingly, if the atoms have larger ionized potentials (atoms with many electric charges), the atoms are likely to be concentrated at the center portion. When different sputtering atoms collide with one another in a transporting process, atoms having a small mass are scattered to a large extent as compared with atoms having a large mass. However, in the same manner as in the magnetron sputtering, a magnetic flux parallel to the target is formed, thereby making it possible to solve the above problem and obtain a substantially uniform thickness and composition of a film.

FIG. 21 shows an image of atomic movement of a target with erosion. In the magnetron sputtering, a portion just above an erosion area (erosion) receives an impact of the ions to become a film having a property different from that of other portions. In other words, the atoms sputtered in an erosion part of the target are deposited on a wafer with kinetic energy and an angle different from those in a case where no erosion is provided. When the sputtering is performed by using a target having no erosion, the energy distribution (kinetic energy or direction of motion) of the atoms to be sputtered is balanced. As a result, the PZT to be deposited by sputtering is deposited in an amorphous state with a short-distance order property or in a micro crystallite state. However, in a case where the sputtering is performed by using a target with the erosion, the energy distribution of the atoms to be sputtered becomes unbalanced. Thus, the PZT to be deposited by sputtering is deposited in a state in which even a short-distance order property does not exist. Comparison thereof is shown in FIG. 22 (state in which sputtering atoms are deposited in orderly alignment) and in FIG. 23 (state in which sputtering atoms are deposited out of orderly alignment). As shown in FIG. 22, when the sputtering atoms are deposited in a state in which the short-distance order property exists, the crystallinity of the PZT to be crystallized by a subsequent heat treatment becomes favorable. On the other hand, as shown in FIG. 23, when the sputtering atoms are deposited in a state in which no short-distance order property exists, the crystallinity of the PZT to be crystallized by a subsequent heat treatment remains unfavorable.

Therefore, the present invention has an object to provide a technology for forming a ferroelectric film having favorable crystallinity and enhancing the yield thereof even when sputtering is performed by using a target with erosion being in an advanced stage.

To solve the above problem, the present invention has adopted the following units. In other words, the present invention is a magnetron-sputtering film-forming apparatus including: a vacuum film-forming chamber forming a thin film on a substrate to be processed contained therein; electrostatic chuck units holding the substrate to be processed contained within the vacuum film-forming chamber by electrostatic adsorption, and adjusting a temperature Ts (° C.) of the substrate to be processed; a target arranged to be opposed to the substrate to be processed which is held by the electrostatic chuck units, and causing high-frequency magnetron sputtering to be performed on the substrate to be processed by discharging; gas supplying units capable of adjusting the pressure within the vacuum film-forming chamber, supplying discharge gas to the vacuum film-forming chamber; power supply units applying a discharge voltage between the substrate to be processed and the target, and calculating an integral power consumption L1 (kWh) of an electricity which is discharged by the target until that time; and control units controlling the electrostatic chuck units and the power supply units. In the magnetron-sputtering film-forming apparatus, the control units controls the electrostatic chuck units to adjust the temperature Ts of the substrate to be processed so that the following expression (1) is satisfied, and then applies the discharge voltage.

Ts=T0−a·L1·T0/L: Expression (1)

where, the initial set temperature is represented by T0 (° C.), the constant is represented by a, and the available electric energy of the target is represented by L (kWh).

The above-mentioned magnetron-sputtering film-forming apparatus includes: electrostatic chuck units adjusting a temperature Ts (° C.) of the substrate to be processed; power supply units applying a discharge voltage between the substrate to be processed and the target, and calculating a cumulative integral power consumption of the electricity which is discharged by the target until that time; and control units controlling the electrostatic chuck units and the power supply units. Accordingly, the electrostatic chuck units is controlled by the control units in accordance with the integral power consumption of the electricity which is discharged by the target until that time, thereby making it possible to adjust the temperature of the substrate to be processed.

In the sputtering, the kinetic energy or the direction of motion of when the atoms to be sputtered are adhered to the substrate to be processed varies between cases of presence and absence of the erosion of the target. This is because, in a state where the target surface has a concave erosion, a path for a discharge current flowing between the target and the substrate to be processed is changed or the direction in which the atoms to be sputtered burst out is changed, as compared with a case where the target surface is in a plan surface state. As a result, when the sputtering is continuously performed by using the same target, the erosion develops and a film to be formed on the substrate to be processed becomes unbalanced. Therefore, in order to form a film having favorable crystallinity even when the sputtering is performed by using the target having erosion, it is necessary to adjust the kinetic energy or the direction of motion of the sputtering atoms in accordance with the development of erosion of the target. The sputtering atom has a property of changing the kinetic energy or the direction of motion in accordance with the temperature of the substrate to be processed. Thus, the temperature of the substrate to be processed is adjusted, thereby making it possible to change the crystallinity of the film to be formed on the substrate to be processed.

Then, in the above-mentioned magnetron-sputtering film-forming apparatus, the control units controls the electrostatic chuck units and adjusts the substrate to be processed to a predetermined temperature calculated by the above expression (1), and then the sputtering is performed. In other words, the temperature of the substrate to be processed is adjusted in advance in accordance with the development of erosion of the target, thereby adjusting, when the sputtering is performed, the kinetic energy or the direction of motion of the sputtering atoms to form the film having favorable crystallinity on the substrate to be processed.

As described above, it is possible to form a ferroelectric film having favorable crystallinity and enhance the yield even when the sputtering is performed by using the target with the erosion being in an advanced stage.

Further, to solve the above problems, the present invention provides a magnetron-sputtering film-forming apparatus, including: a vacuum film-forming chamber forming a thin film on a substrate to be processed contained therein; electrostatic chuck units holding the substrate to be processed contained within the vacuum film-forming chamber by electrostatic adsorption, and adjusting a temperature Ts (° C.) of the substrate to be processed; a target arranged to be opposed to the substrate to be processed which is held by the electrostatic chuck units, and causing high-frequency magnetron sputtering to be performed on the substrate to be processed by discharging; gas supplying units capable of adjusting the pressure within the vacuum film-forming chamber, supplying discharge gas to the vacuum film-forming chamber; power supply units applying a discharge voltage between the substrate to be processed and the target, and calculating an integral power consumption L1 (kWh) of an electricity which is discharged by the target until that time; and control units controlling the electrostatic chuck units and the power supply units. In the magnetron-sputtering film-forming apparatus, the control units controls the electrostatic chuck units to adjust the temperature Ts of the substrate to be processed so that the following sequence (1) is satisfied, and then may apply the discharge voltage.

Ts=Tk(L1<L·(k+1)/(n+1)) Sequence (1)

where, k=0, 1, 2, . . . , n: the available electric energy of the target L (kWh).

In other words, when the sputtering is continuously performed on the substrate to be processed, in view of the complicated procedure in which the control units controls the electrostatic chuck units to adjust the temperature of the substrate to be processed every time the sputtering is performed, the substrate to be processed is kept at a certain temperature while the integral power consumption is within a predetermined power consumption. As a result, when the sputtering is continuously performed, the number of adjustments of the temperature of the substrate to be processed is decreased. Thus, it becomes possible to form a ferroelectric film having favorable crystallinity and enhance the yield even when the sputtering is performed by using the target with the erosion being in an advanced stage, and the time required for forming the ferroelectric film is shortened.

Further, in the above-mentioned magnetron-sputtering film-forming apparatus, the sequence (1) may further satisfy T0≧T1≧ . . . ≧Tn. According to the present invention, the temperature Ts (° C.) of the substrate to be processed is gradually decreased in accordance with the development of erosion, so it becomes possible to form a ferroelectric film having favorable crystallinity and enhance the yield even when the erosion develops.

Further, in the above-mentioned magnetron-sputtering film-forming apparatus, the sequence (1) may further satisfy 30≦T0≦80 when 0≦L1≦200, may further satisfy 25≦T1≦75 when 200<L1≦400, and may further satisfy 20≦T2≦50 when 400<L2≦600. According to the present invention, the temperature Ts (° C.) of the substrate to be processed is gradually decreased in accordance with the development of erosion, so it becomes possible to form a ferroelectric film having favorable crystallinity and enhance the yield even when the erosion develops.

Further, the present invention can be recognized from an aspect of a manufacturing method of a semiconductor device. For example, it is possible to: form an insulating film on a semiconductor substrate; form a lower electrode adhesive layer on the insulating film; form a (111) oriented lower electrode on the lower electrode adhesive layer; form an amorphous ferroelectric layer on the (111) oriented lower electrode in a state in which the temperature of the semiconductor substrate is 20 to 100° C.; thermally treat the amorphous ferroelectric layer in a mixed atmosphere of oxidized gas and inert gas; and form an upper electrode on the amorphous ferroelectric layer. According to the present invention, it becomes possible to form a ferroelectric film having favorable crystallinity and enhance the yield of a semiconductor device.

Further, the present invention provides a manufacturing method for a semiconductor device, capable of: forming a semiconductor element on a semiconductor substrate; forming an insulating layer on the semiconductor substrate on which the semiconductor element is formed; forming a contact hole reaching the semiconductor element on the insulating layer; forming a plug having a conductor film connected to the semiconductor element to be embedded in the contact hole; forming a conductive hydrogen barrier layer, a conductive oxygen barrier layer, and a lower electrode on the insulating layer to be in contact with the plug; forming an amorphous ferroelectric layer on the lower electrode in a state in which the temperature of the semiconductor substrate is 20 to 100° C.; thermally treating the amorphous ferroelectric layer in a mixed atmosphere of oxidized gas and inert gas; and forming an upper electrode on the amorphous ferroelectric layer. According to the present invention, it becomes possible to form a ferroelectric film having favorable crystallinity and enhance the yield of the semiconductor device.

Further, in the above-mentioned manufacturing method for a semiconductor device, the amorphous ferroelectric layer may be formed in a state where the temperature of the semiconductor substrate further satisfies 20 to 50° C. According to the present invention, the motion of the sputtering atoms is suppressed, so it becomes possible to form a ferroelectric film having favorable crystallinity and enhance the yield of the semiconductor device.

Further, in the above-mentioned manufacturing method for a semiconductor device, the amorphous ferroelectric film may be formed in a state where the temperature of the semiconductor substrate is about 35° C. According to the present invention, the motion state of the sputtering atoms becomes an optimum state for forming the ferroelectric film having favorable crystallinity, so it becomes possible to enhance the yield of the semiconductor device.

Further, the present invention provides a manufacturing method for a semiconductor device for forming a thin film on a substrate to be processed by: a vacuum film-forming chamber forming a thin film on a substrate to be processed contained therein; electrostatic chuck units holding the substrate to be processed contained within the vacuum film-forming chamber by electrostatic adsorption, and adjusting a temperature Ts (° C.) of the substrate to be processed; a target arranged to be opposed to the substrate to be processed which is held by the electrostatic chuck units, and causing high-frequency magnetron sputtering to be performed on the substrate to be processed by discharging; gas supplying units capable of adjusting the pressure within the vacuum film-forming chamber, supplying discharge gas to the vacuum film-forming chamber; power supply units applying a discharge voltage between the substrate to be processed and the target, and calculating an integral power consumption L1 (kWh) of an electricity which is discharged by the target until that time; and control units controlling the electrostatic chuck units and the power supply units. In the manufacturing method for a semiconductor device, the control units controls the electrostatic chuck units to adjust the temperature Ts of the substrate to be processed so that the following expression (1) is satisfied, and controls the power supply units to apply the discharge voltage.

Ts=T0−a·L1·T0/L: Expression (1)

where, the initial set temperature is represented by T0 (° C.), the constant is represented by a, and the available electric energy of the target is represented by L (kWh).

According to the present invention, it becomes possible to form a ferroelectric film having favorable crystallinity and enhance the yield even when the sputtering is performed by using the target with the erosion being in an advanced stage.

Further, the present invention provides a manufacturing method for a semiconductor device for forming a thin film on a substrate to be processed by: a vacuum film-forming chamber forming a thin film on a substrate to be processed contained therein; electrostatic chuck units holding the substrate to be processed contained within the vacuum film-forming chamber by electrostatic adsorption, and adjusting a temperature Ts (° C.) of the substrate to be processed; a target arranged to be opposed to the substrate to be processed which is held by the electrostatic chuck units, and causing high-frequency magnetron sputtering to be performed on the substrate to be processed by discharging; gas supplying units capable of adjusting the pressure within the vacuum film-forming chamber, supplying discharge gas to the vacuum film-forming chamber; power supply units applying a discharge voltage between the substrate to be processed and the target, and calculating an integral power consumption L1 (kWh) of an electricity which is discharged by the target until that time; and control units controlling the electrostatic chuck units and the power supply units. In the manufacturing method for a semiconductor device, the control units controls the electrostatic chuck units to adjust the temperature Ts of the substrate to be processed so that the following sequence (1) is satisfied, and controls the power supply units to apply the discharge voltage.

Ts=Tk(L1<L·(k+1)/(n+1)) Sequence (1)

where, k=0, 1, 2, . . . , n: the available electric energy of the target L (kWh).

According to the present invention, it becomes possible to form a ferroelectric film having favorable crystallinity and enhance the yield even when the sputtering is performed by using the target with the erosion being in an advanced stage, and the time required for forming the ferroelectric film is shortened.

According to the present invention, it becomes possible to form a ferroelectric film having favorable crystallinity and enhance the yield even when the sputtering is performed by using the target with the erosion being in an advanced stage.

### BRIEF DESCRIPTION OF THE DRAWINGS

FIG. 1 is a flowchart showing a manufacturing process of a ferroelectric memory according to Embodiment 1 of the present invention;

FIG. 2 is a cross-sectional view of a manufacturing process of a FeRAM according to Embodiment 1 of the present invention;

FIG. 3 is a cross-sectional view of a manufacturing process of the FeRAM according to Embodiment 1 of the present invention;

FIG. 4 is a cross-sectional view of a manufacturing process of the FeRAM according to Embodiment 1 of the present invention;

FIG. 5 is a cross-sectional view of a manufacturing process of the FeRAM according to Embodiment 1 of the present invention;

FIG. 6 is a cross-sectional view of a manufacturing process of the FeRAM according to Embodiment 1 of the present invention;

FIG. 7 is a cross-sectional view of a manufacturing process of the FeRAM according to Embodiment 1 of the present invention;

FIG. 8 is a schematic view of a sputtering film-forming apparatus according to Embodiment 1 of the present invention;

FIG. 9 is a flowchart showing the sputtering film-forming apparatus according to Embodiment 1 of the present invention;

FIG. 10 is a cross-sectional view of a FeRAM according to Embodiment 2 of the present invention;

FIG. 11A is a graph showing a dependence of an electrostatic chuck temperature on a crystal orientation ratio;

FIG. 11B is a graph showing a dependence of an electrostatic chuck temperature on a crystal orientation ratio;

FIG. 12A is a graph showing a dependence of an electrostatic chuck temperature on a yield;

FIG. 12B is a graph showing a dependence of an electrostatic chuck temperature on a yield;

FIG. 13 is a table showing an electric property of a ferroelectric capacitor;

FIG. 14A is a graph showing a dependence of a crystallinity of a ferroelectric film on a film-forming temperature;

FIG. 14B is a graph showing a dependence of a crystallinity of a ferroelectric film on a film-forming temperature;

FIG. 14C is a graph showing a dependence of a crystallinity of a ferroelectric film on a film-forming temperature;

FIG. 15 is a graph showing an in-plane distribution of a half width of CSPLZT (111) film measured by 4-axis XRD;

FIG. 16A is a graph showing a PT yield of a 1T1C device and a PT ratio thereof;

FIG. 16B is a graph showing a PT yield of a 1T1C device and a PT ratio thereof;

FIG. 17 is a graph showing the film-forming temperature which is most suitable for a CSPLZT target life;

FIG. 18 is a graph showing the film-forming temperature which is suitable for an operation of mass production and is most suitable for a CSPLZT target life;

FIG. 19 is a graph showing an erosion distribution of a target obtained when sputtering is carried out by a sputtering film-forming apparatus according to the prior art;

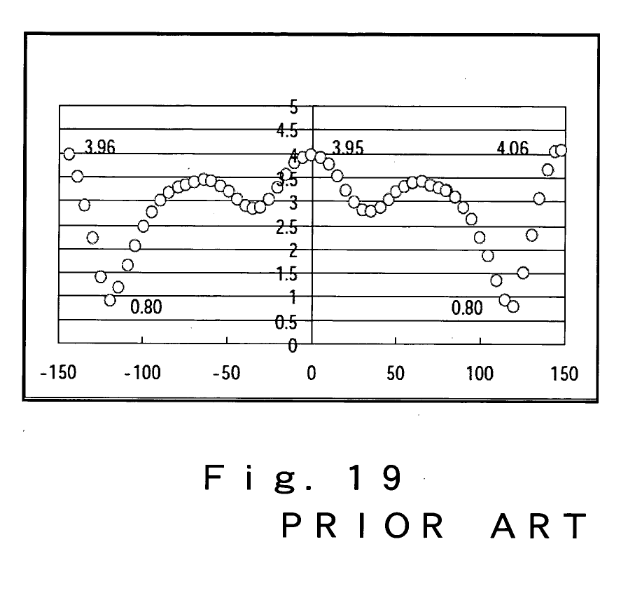

FIG. 20 is a schematic view of a sputtering film-forming apparatus according to the prior art;

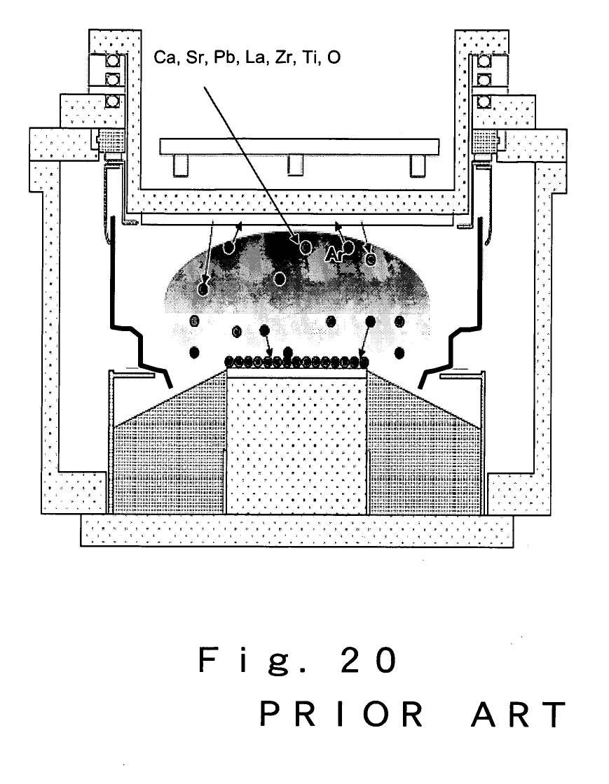

FIG. 21 is a diagram showing a state of sputtering atoms obtained when sputtering is carried out by the sputtering film-forming apparatus according to the prior art;

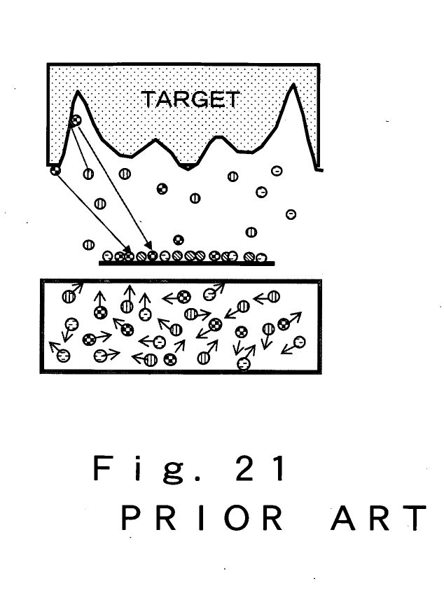

FIG. 22 is a diagram showing a state in which sputtering atoms are deposited in orderly alignment; and

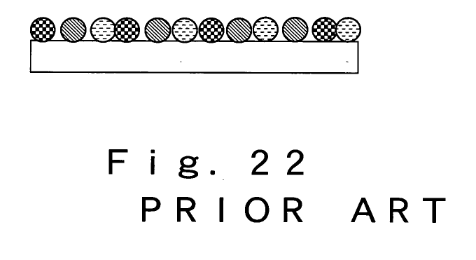

FIG. 23 is a diagram showing a state in which sputtering atoms are deposited out of orderly alignment.

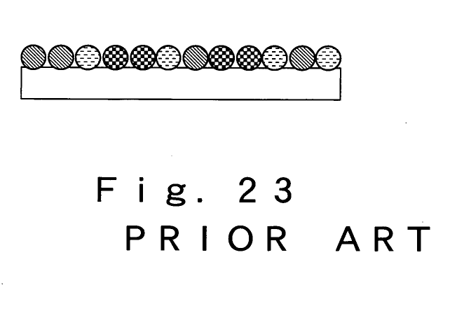

### DETAILED DESCRIPTION OF THE INVENTION

Hereinafter, embodiments of the present invention will be described by illustration. The embodiments to be described below are an illustration, so the present invention is not limited thereto.

### Embodiment 1

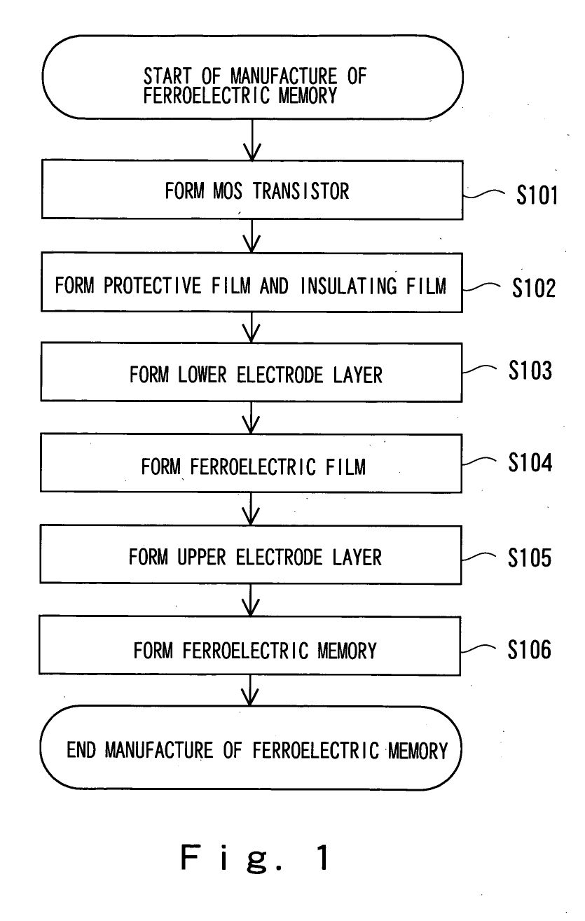

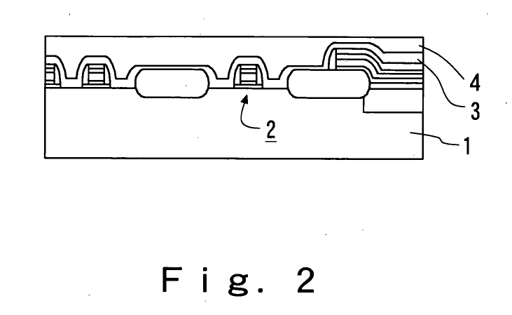

FIGS. 1 to 6 are flow charts showing a manufacturing process in a case where a FeRAM having a planar structure is manufactured by using a magnetron-sputtering film-forming apparatus and a manufacturing method for a semiconductor device according to a first embodiment (hereinafter, referred to as “Embodiment 1”) of the present invention, and showing a cross-sectional view of the FeRAM. Hereinafter, referring to the flowchart of FIG. 1, each step will be explained.

<Step 1> As shown in FIG. 2, an MOS transistor 2 serving as a selection transistor is formed on a silicon semiconductor substrate 1 in the following step (S101).

First, on a surface layer of the silicon semiconductor substrate 1, an element isolation structure is formed by, for example, Shallow Trench Isolation (STI) method to determine an element active region. Next, impurities such as B (boracic acid) are implanted into the element active region by ion implantation under the condition that the dose amount is 3.0·10¹³/cm² and the acceleration energy is 300 keV to form a well. A thin gate insulating film having a thickness of about 3.0 nm is formed in the element active region by the thermal oxidation method. Further, a multicrystalline silicon film having a thickness of about 180 nm and, for example, a silicon nitrogen film having a thickness of about 29 nm are deposited on the gate insulating film by a chemical vapor deposition (CVD) method. Pattern electrodes are formed from the silicon nitrogen film, the multicrystalline silicon film, and the gate insulating film by photolithography and dry etching. As a result, a cap film having the silicon nitrogen film on the gate electrode is formed in a pattern. Subsequently, impurities such as As (arsenic) are implanted into the element active region by ion implantation by using the cap film as a mask under the condition that the dose amount is 5.0·10¹⁴/cm² and the acceleration energy is 10 keV to form an LDD region. Then, a silicon dioxide film, for example, is deposited by the CVD method, and further an etchback is performed, to thereby form a side-wall insulating film composed of oxide silicon on a side of the gate electrode and the cap film. Next, by using the cap film and the side-wall insulating film as masks, impurities such as P (phosphorus) are implanted into the element active region by ion implantation under the condition in which a contaminant concentration is higher than that in the LDD region, for example, with the dose amount of 5.0·10¹⁴/cm² and the acceleration energy of 13 keV. As a result, a source/drain region is formed to be superposed with the LDD region. As described above, the MOS transistor 2 is completed.

<Step 2> Subsequently, a protective film 3 and an interlayer insulating film 4 of the MOS transistor 2 is formed in the following step (S102).

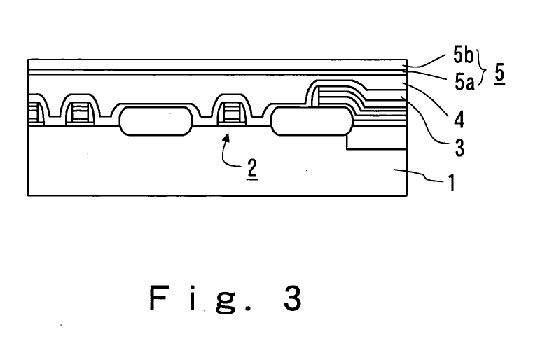

First, a protective film 3 composed of a silicon dioxide film is formed with a thickness of about 20 nm by the CVD method. Next, a laminated structure in which, for example, a plasma SiO₂ film (having a thickness of about 20 nm), a plasma SiN film (having a thickness of about 80 nm), and a plasma TEOS film (having a thickness of about 1000 nm) are sequentially formed, is formed, and is polished by the Chemical Mechanical Polishing (CMP) method to obtain a thickness of about 700 nm. As a result, the interlayer insulating film 4 is formed.

<Step 3> Next, as shown in FIG. 3, a lower electrode layer 5 is formed on the interlayer insulating film 4 in the following step (S103).

First, a lower electrode adhesive film 5a having a thickness of about 20 nm, for example, is formed on the interlayer insulating film 4 by the sputtering method. In this embodiment, the lower electrode adhesive film 5a is made of aluminum oxide, but may be made of aluminum nitride, tantalum oxide, titanium oxide, zirconium oxide, and the like. It should be noted that, in order to enhance the crystallinity of a lower electrode 5b formed on the lower electrode adhesive film 5a, the lower electrode adhesive film 5a is preferably thermally treated (annealed) at 650° C. for 60 seconds in an oxygen atmosphere by the Rapid Thermal Annealing (RTA) method.

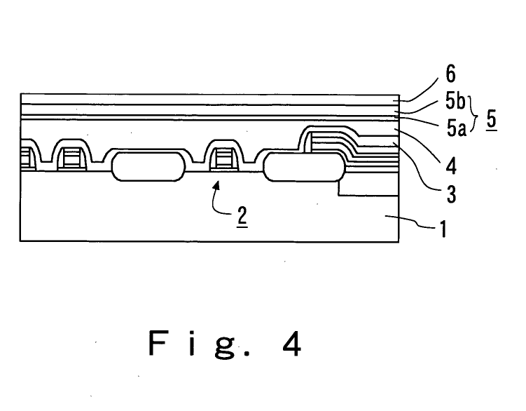

Next, the lower electrode 5b composed of Pt (platinum) and having a thickness of about 150 nm, for example, is formed on the lower electrode adhesive film 5a by the sputtering method. In order for Pt contained in the lower electrode 5b to be made into a crystallization having a (111) orientation, it is preferable that, for example, by setting the temperature of the silicon semiconductor substrate 1 to 350° C. or higher with a power of 0.3 kW, the sputtering is performed to form a film. It should be noted that the lower electrode 5b is made of Pt in this embodiment, but may be made of Ir, Ru, Rh, Re, Os, Pd, an oxide thereof, SrRuO₃, other conductive oxides, or a laminated structure thereof.

<Step 4> Subsequently, as shown in FIG. 4, a ferroelectric film 6 is formed on the lower electrode layer 5 in the following step (S104).

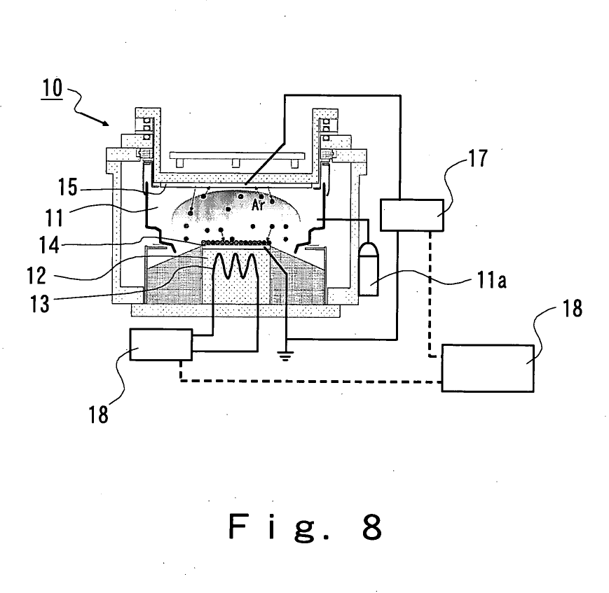

First, by the RF magnetron sputtering method, the ferroelectric film 6 is formed on the lower electrode layer 5. The thickness of the ferroelectric film 6 is, for example, 70 to 250 nm, and the ferroelectric film 6 of this embodiment is formed with a thickness of 150 nm. When the ferroelectric film 6 is formed, a low-temperature electrostatic chuck (corresponding to the electrostatic chuck of the present invention) is used to perform sputtering while the temperature of the silicon semiconductor substrate 1 is controlled. The temperature of the silicon semiconductor substrate 1 affects the temperature of the sputtering atoms, the kinetic energy, and the direction of motion. In order to improve the crystallinity of the ferroelectric film 6, it is preferable that the sputtering is performed by setting the temperature of the silicon semiconductor substrate 1 to 100° C. or lower. In a case where the sputtering is performed by setting the temperature of the silicon semiconductor substrate 1 to 100° C. or higher, the kinetic energy of the sputtering atoms is changed to a large extent. As a result, PZT having no short-distance order property is deposited. When the PZT deposited with no short-distance order property is thermally treated to be crystallized, crystallization having a (101) orientation is formed, thereby deteriorating the property as the ferroelectric substance of the capacitor. Note that it is possible that the ferroelectric film 6 is formed by thermally treating the film in which a crystalline structure becomes, for example, Bi layer structure or a perovskite structure. Examples of the film include, in addition to a film made of PZT, a film made of PZT, SBT, BLT, which is doped with a slight quantity of La, Ca, Sr and/or Si and the like, and a film expressed by a general formula ABO₃ such as Bi-based layer compound. Further, in addition to these films, the ferroelectric film 6 may be formed by a Zr-oxide film, a film of a Pb-based film, and the like. It should be noted that the magnetron-sputtering film-forming apparatus will be described below (see FIG. 8).

Next, by the RTA method, for example, heat treatment is performed in a mixed atmosphere of inert gas and oxygen. As conditions of the heat treatment, for example, the temperature of the silicon semiconductor substrate 1 is set to 550° C. to 800° C. (for example, 580° C. in this embodiment), the atmosphere is set to 50 sccm of oxygen and 2000 sccm of Ar, and the time period for heat treatment is set to 30 seconds to 120 seconds (for example, 90 seconds). The conditions of the heat treatment are changed according to a type of composition forming the ferroelectric film 6. The temperature of the heat treatment is preferably set to 600° C. or lower in a case where the composition of the ferroelectric film 6 is PZT, is preferably set to 700° C. or lower in a case of BLT, and is preferably set to 800° C. or lower in a case of SBT.

<Step 5> Subsequently, an upper electrode layer 7 is formed on the ferroelectric film 6 in the following step (S105).

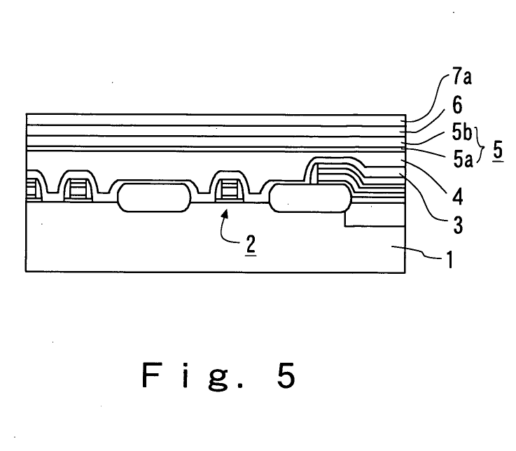

First, as shown in FIG. 5, by the sputtering method or the MOCVD method, the upper electrode 7a is formed with a thickness of, for example, 10 nm to 100 nm (50 nm in this embodiment). The upper electrode 7a is composed of IrO_{X} (for example, IrO₁). Next, the upper electrode 7a is thermally heated by the RTA method (in a mixed atmosphere of inert gas and oxygen). As conditions of the heat treatment, the temperature of the heat treatment is set to 650° C. to 800° C. (for example, 700° C.), the atmosphere is set to 20 sccm of oxygen and 2000 sccm of Ar, and the time period for heat treatment is set to 30 seconds to 120 seconds (60 seconds in this embodiment). By the heat treatment, the PZT of the ferroelectric film 6 is completely crystallized, and at the same time, an interface between the ferroelectric film 6 and the upper electrode 7a is made flat. When the interface between the ferroelectric film 6 and the upper electrode 7a is made flat, the electric property of the capacitor is enhanced.

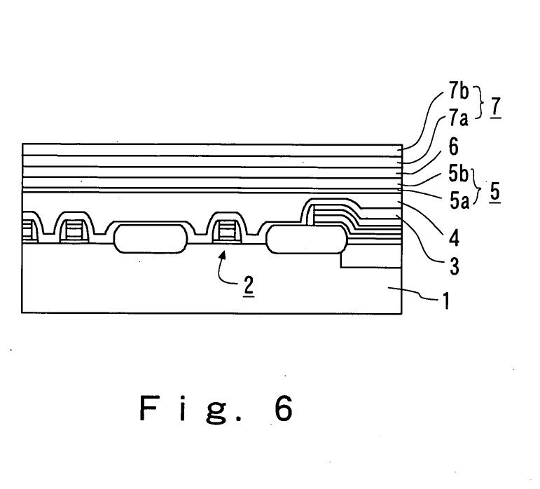

Next, as shown in FIG. 6, an upper electrode adhesive layer 7b (oxygen barrier film) with a thickness of 100 nm to 300 nm is formed on the ferroelectric film 6. A material of the upper electrode adhesive layer 7b is IrO_{Y}. In this case, in order to prevent a process degradation, relative proportions of the oxygen IrO_{Y} contains of the upper electrode adhesive layer 7b are set to be higher than those of the oxygen IrO_{X} contains of the upper electrode 7a (for example, IrO₂ or IrO₄). It should be noted that, instead of IrO₂, the material of the upper electrode adhesive layer 7b may be Ir, Ru, Rh, Re, Os, Pd, an oxide thereof, SrRuO₃, other conductive oxides, or a laminated structure thereof.

<Step 6> Subsequently, a ferroelectric memory 9 is formed in the following step (S106). First, the upper electrode adhesive layer 7b is cleaned and then the upper electrode layer 7 is processed by patterning. Next, in an atmosphere of O₂, an annealing recovery process is performed with a temperature of 650° C. for 60 minutes. The heat treatment recovers a physical damage received by the ferroelectric film 6 when the upper electrode layer 7 is formed. After that, patterning is applied to the ferroelectric film 6. Subsequently, the oxygen annealing is performed to prevent an Al₂O₃ film to be formed later from being peeled off.

Next, as a protective film for protecting a ferroelectric capacitor 8, an Al₂O₃ film is formed by the sputtering method. Then, the oxygen annealing is performed to alleviate damage due to the sputtering. The protective film (Al₂O₃) prevents hydrogen from intruding into the ferroelectric capacitor 8 from an outside. After that, patterning is applied to the Al₂O₃ film and the lower electrode layer 7. Subsequently, the oxygen annealing is performed to prevent the Al₂O₃ film to be formed later from being peeled off.

Next, as the protective film, the Al₂O₃ film is formed on the whole surface thereof by the sputtering method. Then, the oxygen annealing is performed to reduce capacitor leakage. After that, an interlayer insulating film is formed on the whole surface thereof by the high-density plasma method. The thickness of the interlayer insulating film is set to, for example, about 1.5 μm.

Next, by the Chemical Mechanical Polishing (CMP) method, planarization of the interlayer insulating film is performed. Next, plasma processing with N₂O gas is performed. As a result, a surface part of the interlayer insulating film is nitrided to some extent, thereby preventing moisture from intruding into an inside thereof. Note that, in the plasma processing, gas containing at least one of nitrogen and oxygen is preferably used. Next, a contact hole reaching a diffused region of the MOS transistor 2 is formed on an interlayer insulating film, an Al₂O₃ film, a Ti film, a silicon dioxide film, and a silicon oxynitride film. After that, by the sputtering method, a Ti film and a TiN film are continuously formed within the contact hole, thereby forming an adhesive film (a barrier metal film). Next, a W film is formed in the contact hole in which an adhesive film is formed by the chemical vapor deposition (CVD) method. Then, planarization of the W film is performed by the CMP method. As a result, a W plug is formed.

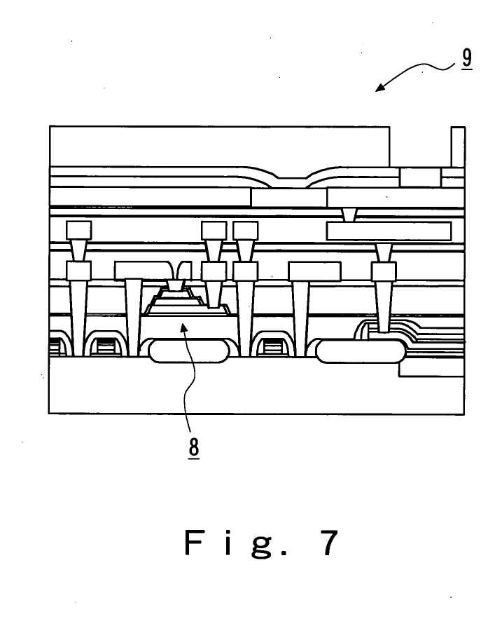

Next, an SION film is formed as an oxidation resistant film of the W plug by, for example, the plasma CVD method. Then, the contact hole reaching the upper electrode adhesive layer 7b and the contact hole reaching the lower electrode 5b are formed on the SiON film, the interlayer insulating film, and the Al₂O₃ film. After that, in order to recover the damage of the ferroelectric film 6, the oxygen annealing is performed. Subsequently, the SiON film is etched back to be removed, whereby an upper surface of the W plug is exposed. In a state where a part of the surface of the upper electrode adhesive layer 7b, a part of the surface of the lower electrode 5b, and the surface of the W plug are exposed, an Al film is formed, and wiring patterning is applied to the Al film, thereby forming a wiring. It should be noted that the W plug and the upper electrode adhesive layer 7b, or the lower electrode 5b and the wiring, respectively, are formed to be electrically connected to each other. After that, further, an interlayer insulating film is formed, a contact plug is formed, and wirings in a second layer and the subsequent layers are formed, for example. Then, a cover film composed of the TEOS oxide film and the SiN film is formed. As described above, the ferroelectric memory 9 including the ferroelectric capacitor 8 shown in FIG. 7 is completed.

<Supplement> Referring to FIG. 8, a magnetron-sputtering film-forming apparatus 10 used in the above-mentioned <Step 4> will be described.

FIG. 8 is a schematic view of the structure of the magnetron-sputtering film-forming apparatus 10 according to the present invention. As shown in FIG. 8, an electrostatic chuck 12 is provided on a floor of a vacuum film-forming chamber 11 in a table-like manner. An electric heater 13 is incorporated into the electrostatic chuck 12, and it is possible to keep a substrate to be processed 14, which is held on an upper surface of the electrostatic chuck 12, at predetermined temperature by the electric heater 13 by electrostatic adsorption. On the other hand, on a ceiling of the vacuum film-forming chamber 11, a target 15 is provided so that the electrostatic chuck 12 is positioned upwardly. It should be noted that the inside of the vacuum film-forming chamber is filled with discharge gas by a gas supplying apparatus 11a, and a power supply 17 has a function for measuring a integral power consumption of discharged energy of the target 15.

The electric heater 13 is controlled by an electrostatic chuck apparatus 16 so that the substrate to be processed 14 is kept at the predetermined temperature. The target 15 and the electrostatic chuck 12 are electrically connected to the power supply 17 (corresponding to a power supply units in the present invention), respectively, and have a structure in which a discharge voltage is applied therebetween. The electrostatic chuck apparatus 16 and the power supply 17 are structured to be controlled by a control apparatus 18.

The magnetron-sputtering film-forming apparatus 10 is structured as described above, thereby making it possible to perform sputtering while the temperature of the substrate to be processed 14 is adjusted by the control apparatus 18.

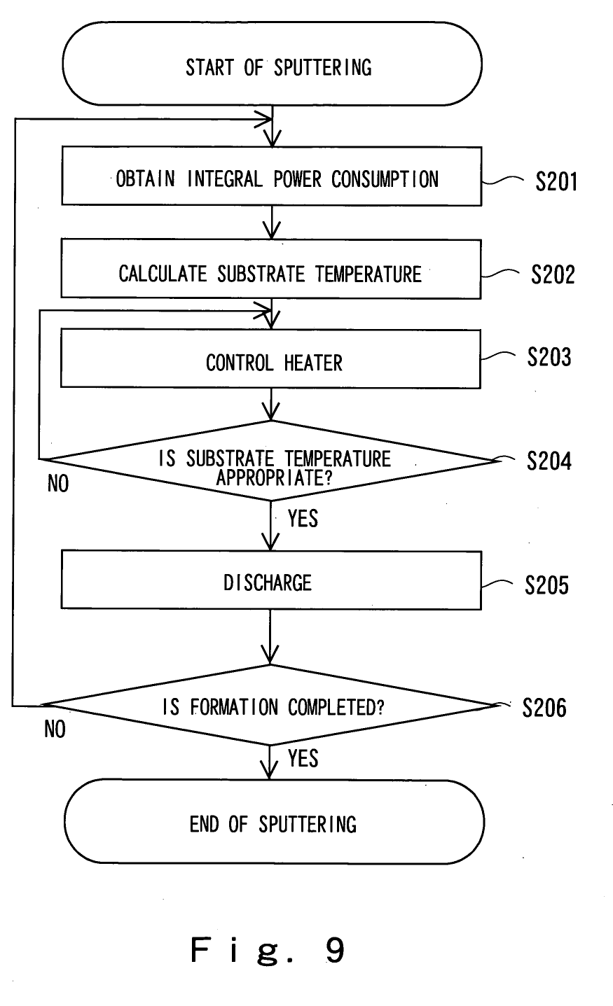

Next, a controlling method performed when the ferroelectric film 6 is formed by using the magnetron-sputtering film-forming apparatus 10 according to the present invention will be described referring to FIG. 9.

Upon receiving an instruction to start the sputtering, the control apparatus 18 obtains from the power supply 17 the integral power consumption in the sputtering process of the target 15 (S201). This is because the development of erosion is determined by the integral power consumption for every target 15, and the development of the erosion of the target is obtained, thereby adjusting the temperature of the substrate to be processed 14 according to the development of erosion.

Next, the control apparatus 18 calculates the temperature Ts of the substrate to be processed by the following expression (1) or sequence (1) from the obtained integral power consumption (S202). The kinetic energy or the direction of the motion of the sputtering atoms is changed in accordance with the temperature of the substrate to be processed 14. As a result, when the sputtering is performed, the temperature of the substrate to be processed 14 is adjusted to be kept at the predetermined temperature in accordance with the development of erosion of the target (integral power consumption), thereby making it possible to put the kinetic energy and the direction of motion of the sputtering atoms into an optimum state for forming the ferroelectric film 6. In other words, the temperature of the substrate to be processed 14 is adjusted, thereby making it possible to change the crystallinity of the film formed on the substrate to be processed 14.

Ts=T0−a·L1·T0/L Expression (1)

where, the initial set temperature is represented by T0 (° C.), a constant is represented by a, and the available electric energy of the target is represented by L (kWh).

Ts=Tk(L1<L·(k+1)/(n+1)) Sequence (1)

where, k=0, 1, 2, . . . , n: the available electric energy of the target L (kWh).

Next, the control apparatus 18 controls the electrostatic chuck apparatus 16 to activate the electric heater 13, thereby controlling the temperature of the substrate to be processed 14 to be the temperature Ts of the substrate to be processed (S203).

Confirming that the substrate to be processed 14 reaches the temperature Ts of the substrate to be processed (S204), the control apparatus 18 activates the power supply 17 to apply the discharge voltage between the target 15 and the electrostatic chuck 12, thereby performing the sputtering.

Judging from the integral power consumption of the discharged electricity that the ferroelectric film 6 is formed on the substrate to be processed 14, the control apparatus 18 completes the sputtering. On the other hand, when judging that the ferroelectric film 6 is not formed, the control apparatus 18 returns to S201 and executes the process again. It should be noted that instead of returning to S201 to readjust the temperature of the substrate to be processed 14, the control apparatus 18 may repeat S205 and S206 a predetermined number of times and then may return to S201, or may complete the sputtering at that time. As a result, there is no need to adjust the temperature of the substrate to be processed 14 in each case of discharging, so the formation of the ferroelectric film 6, in other words, the productivity of the ferroelectric memory is enhanced.

As described above, according to the magnetron-sputtering film-forming apparatus 10 of Embodiment 1, even when sputtering is performed by using a target with erosion being in an advanced stage, it is possible to form a ferroelectric film having favorable crystallinity and enhance the yield of an FeRAM. That is, the dependence of the temperature of the silicon semiconductor substrate 1 on the integral power consumption of the discharged energy of the target is utilized to automatically control the temperature of the silicon semiconductor substrate 1, thereby making it possible to prevent the deterioration of the short-distance order property of the PZT to be deposited. It is possible to deposit the PZT in a state where the deterioration of the short-distance order property is prevented, thereby making it possible to form the ferroelectric film in a favorable crystalline state when the PZT is thermally treated to be crystallized. As a result, it is possible to provide a FeRAM device with a high yield and high reliability.

### Embodiment 2

Next, a second embodiment (hereinafter, referred to as “Embodiment 2”) of the present invention will be described. The above-mentioned Embodiment 1 illustrates the case where the present invention is applied to manufacture of a planar-type ferroelectric capacitor 8. Embodiment 2 illustrates a case where the present invention is applied to manufacture of a stacked-type ferroelectric capacitor 9.

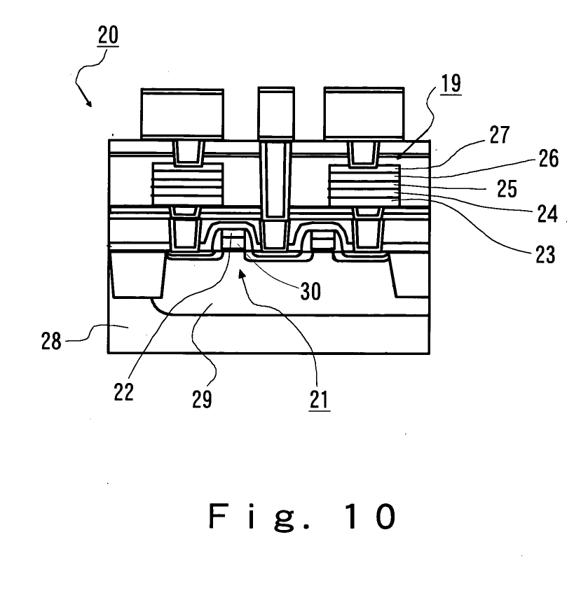

FIG. 10 is a sectional view of the FeRAM 20 according to this embodiment. A silicon substrate 28 is a p-type or n-type silicon, an element region 29 is formed in a shape of n-type well by an STI-type element isolation structure. In the element region 29, a gate electrode 22 constituting a part of the MOS transistor 21 is formed via a gate insulating film 30. Further, on the silicon substrate 28, a p-type LDD region is formed by ion implantation using the gate electrode 22 as a mask. On each of the gate electrode 22, a silicide layer (not shown) is formed. Furthermore, a side wall insulating film is formed on a side wall of the gate electrode 22. A p-type diffused region is formed on the p-type LDD region by ion implantation using the gate electrode 22 and the side wall insulating film as masks.

Next, the SiON film having a thickness of about 200 nm is formed by the plasma CVD method. Further, an interlayer insulating film composed of a silicon dioxide film and having a thickness of 1000 nm is formed by the plasma CVD method. The planarization of the interlayer insulating film is performed by the CMP method, and the thickness of the interlayer insulating film is set to 700 nm. A contact hole is formed in the interlayer insulating film, and the above-mentioned diffused region is exposed. The contact hole is formed with, for example, a diameter of 0.25 μm. A first plug electrically connected to the diffused region is formed with the contact hole. First, a Ti film having a thickness of 30 nm is formed within the contact hole. Then, on the Ti film, a TiN film having a thickness of 20 nm is formed. A W film is loaded on the TiN film to fill the hole by the CVD method and an excess W film is removed by the CMP method. As a result, the first plug is formed.

Next, a first oxidation resistant film composed of SiON is formed by the plasma CVD method. The first oxidation resistant film is formed with, for example, a thickness of 130 nm. Then, on the first oxidation resistant film, an interlayer insulating film composed of a silicon dioxide film is formed with, for example, a thickness of 300 nm by the plasma CVD method using TEOS as a material. Further, formed is a contact hole penetrating the first oxidation resistant film and the interlayer insulating film and exposing the upper surface of the first plug. Within the contact hole, a second plug electrically connected to the first plug is formed by the same method mentioned above.

Next, the surface of the interlayer insulating film is processed by an ammonia plasma, thereby combining an atom of oxygen on the surface of the interlayer insulating film with an NH group. As a result, even when Ti atoms are deposited on the interlayer insulating film, the Ti atoms are not captured by the atom of oxygen. In other words, the Ti atoms can move freely on the upper surface of the interlayer insulating film. Therefore, when the Ti atoms are deposited on the interlayer insulating film by, for example, the sputtering method, it is possible to form the Ti film self-assembled in a (002) orientation. It should be noted that, in the ammonia plasma treatment, used is a parallel plate type plasma treatment apparatus including counter electrodes which are apart from the substrate to be processed by about 9 mm (350 mils). As conditions of the ammonia plasma treatment, under a pressure of 266 Pa (2 Torr), ammonia gas is supplied at a flow rate of 350 sccm in a treatment container which is kept at the substrate temperature of 400° C., a high frequency wave of 13.56 MHz with a power of 100 W is supplied to a side of the substrate to be processed, and a high frequency wave of 350 kHz with a power of 55 W is supplied to a side of the counter electrode for 60 seconds.

Next, using the sputtering method, in a sputtering apparatus in which a distance between the substrate to be processed and the target is set, for example, to 60 mm, in an atmosphere of Ar of 0.15 Pa, at the substrate temperature of 20° C., a sputter DC power of 2.6 kW is supplied for 7 seconds, thereby forming a Ti film having a strong (002) orientation.

Then, heat treatment is performed in a nitrogen atmosphere at the temperature of 650° C. for 60 seconds by the RTA method, thereby forming a TiN film having a (111) orientation. Next, a lower electrode adhesive layer 23 (TiAlN film) serving as an oxygen barrier film having a thickness of 100 nm is formed by the reactive sputtering method (in a mixed atmosphere of Ar of 40 sccm and nitrogen of 10 sccm, under a pressure of 253.3 Pa, at the substrate temperature of 400° C., and with a sputtering power of 1.0 kW) using a target in which Ti and Al are alloyed. After that, using the sputtering method (in an Ar atmosphere, under a pressure of 0.11 Pa, at the substrate temperature of 500° C., and with a sputtering power of 0.3 kW), a lower electrode 24 (a Pt film) with a thickness of 100 nm is formed on the lower electrode adhesive layer 23.

It should be noted that the lower electrode 24 may be composed of a Pt/Ir laminated film, metals of the platinum family such as Ir, or conductive oxides such as PtO, IrOx, SrRuO₃, instead of the Pt film. Further, the lower electrode 24 may also be a laminated film composed of the above-mentioned metals or metal oxides.

Next, in the same manner as the above-mentioned Embodiment 1, on the lower electrode 24, by the sputtering method while controlling the temperature of the silicon substrate 28 using a low-temperature electrostatic chuck, a ferroelectric film 25 (a PZT film) is formed. The ferroelectric film 25 is formed with, for example, a thickness of 70 nm to 250 nm (for example, 120 nm).

Next, in the same manner as the above-mentioned Embodiment 1, heat treatment is performed in a mixed atmosphere of inert gas and oxygen by the RTA method and the like. As conditions of the heat treatment, as in Embodiment 1, the heat treatment temperature is set to, for example, 550° C. to 800° C. (for example, 580° C.), in an atmosphere of oxygen of 50 scam and Ar of 2000 scam, and the heat treatment time is set to 30 seconds to 120 seconds (for example, 90 seconds).

Next, an upper electrode 26 is formed by the same method as Embodiment 1.

Next, by the same method as Embodiment 1, an upper electrode adhesive layer 27 (an Ir film) serving as a hydrogen barrier film is formed on the upper electrode 26. Then, a back surface cleaning is performed to sequentially form a titanium nitride film and a silicon dioxide film using the TEOS which are used as masks when patterning is applied to the upper electrode adhesive layer 27, the upper electrode 26, the ferroelectric film 25, the lower electrode 24, and the lower electrode adhesive layer 23. The titanium nitride film is formed, for example, at the temperature of 200° C. and with a thickness of about 200 nm. The silicon dioxide film is formed, for example, at 390° C. and with a thickness of about 390 nm.

Next, patterning is applied to the silicon dioxide film and the titanium nitride film, thereby forming hard masks only in a region in which a stacked-type ferroelectric capacitor is to be formed. Next, by adopting the technology of patterning and etching using the silicon dioxide film and the titanium nitride film as masks, the upper electrode adhesive layer 27, the upper electrode 26, the ferroelectric film 25, the lower electrode 24, and the lower electrode adhesive layer 23 are processed all at once, to thereby form the ferroelectric capacitor 19 with a stacked structure. After that, the hard masks (the silicon dioxide film and the titanium nitride film) are removed. Subsequently, in an oxygen atmosphere, heat treatment is performed, for example, at the temperature of 300° C. to 500° C. for 30 minutes to 120 minutes.

Next, to cover the interlayer insulating film and the ferroelectric capacitor 19, the Al₂O₃ film is first formed with a thickness of 20 nm by the sputtering method, and thermally treated in the oxygen atmosphere at the temperature of 600° C. As a result, an oxygen deficiency caused in the ferroelectric capacitor 19 by the patterning is recovered. Further, the Al₂O₃ film is formed with a thickness of 20 nm by the CVD method.

Next, by the plasma CVD method, for example, an interlayer insulating film composed of a silicon oxide with a thickness of 1500 nm is formed. In a case where the silicon dioxide film is formed as the interlayer insulating film, as a source gas, for example, mixed gas of TEOS gas, oxygen gas, and helium gas is used. It should be noted that, as the interlayer insulating film, for example, an inorganic film having insulation properties may be formed. After the formation of the interlayer insulating film, planarization of the surface of the interlayer insulating film is performed by, for example, the CMP method.

Subsequently, in an atmosphere of plasma generated by using N₂O gas or N₂ gas and the like, heat treatment is performed. As a result of the heat treatment, moisture contained in the interlayer insulating film is removed, and a quality of the interlayer insulating film is changed, thereby preventing moisture from intruding into an inside of the interlayer insulating film. After that, a barrier film is formed on the entire surface thereof by, for example, the sputtering method or the CVD method. As the barrier film, for example, an aluminum oxide film having a thickness of 20 nm to 100 nm is formed. The barrier film is formed on the planarized interlayer insulating film, so the barrier film is planarized.

Next, the interlayer insulating film is formed by the plasma CVD method. As the interlayer insulating film, for example, a silicon dioxide film having a thickness of 800 nm to 1000 nm is formed. It should be noted that, as the interlayer insulating film, a SiON film, a silicon oxynitride film, or the like may be formed. Next, the surface of the interlayer insulating film is planarized by, for example, the CMP method.

Next, a contact hole is formed in the interlayer insulating film. The contact hole is formed and the upper electrode adhesive layer 27 (hydrogen barrier film) is exposed, and then heat treatment is performed in the oxygen atmosphere at the temperature of 550° C., thereby recovering an oxygen deficiency caused in the ferroelectric film 25 (the PZT film) in association with the formation of the contact hole. Then, within the contact hole, a via plug electrically connected to the upper electrode adhesive layer 27 of the ferroelectric capacitor 19 is formed.

It should be noted that, when a conductive plug is formed within the contact hole, it is preferable to form a TiN film on an inner surface of the contact hole in a single layer as an adhesive layer. As the adhesive layer, the Ti film is formed by the sputtering method, and a TiN film is formed thereon by the MOCVD method. As a result, it is possible to form the adhesive layer. In this case, in order to remove carbon from the TiN film, it is necessary to perform the processing in mixed gas plasma including nitrogen and hydrogen. However, in this embodiment, the upper electrode adhesive layer 27 is the hydrogen barrier composed of Ir, so the upper electrode 26 is not reduced by hydrogen.

Further, on the interlayer insulating film, a wiring pattern electrically connected to the via plug is formed. The sputtering method, for example, sequentially formed are a Ti film having a thickness of 60 nm, a TiN film having a thickness of 30 nm, an AlCu alloy film having a thickness of 360 nm, a Ti film having a thickness of 5 nm, and a TiN film having a thickness of 70 nm. As a result, a laminated film composed of the Ti film, the TiN film, the AlCu alloy film, and the Ti film and the TiN film is formed. Next, using a technology of photolithography, patterning is applied to the laminated film. As a result, a wiring (first metal wiring layer) composed of the laminated film is formed. After that, further, formation of the interlayer insulating film, formation of the contact plug, formation of wirings of second to fifth layers and subsequent layers, and the like are performed. Then, a cover film composed of a TEOS oxide film and a SiN film is formed. As a result, the FeRAM 20 including the ferroelectric capacitor is completed.

### Embodiment 3

In an initial stage of a CSPLZT target (the integral power consumption of 120 kWh) in a case where the ferroelectric memory is manufactured in the same manner as in Embodiment 1, by using the capacitor composed of the lower electrode adhesive layer 5a (Pt), the lower electrode 5b (AlO), the ferroelectric film 6 (CSPLZT), an upper electrode 7a (IrO₁), and the upper electrode adhesive layer 7b (IrO₄), the dependence of each of the crystallinity of the ferroelectric film, the electric property of the capacitor, and a yield of a device upon the electrostatic chuck temperature when the ferroelectric film is formed was monitored.

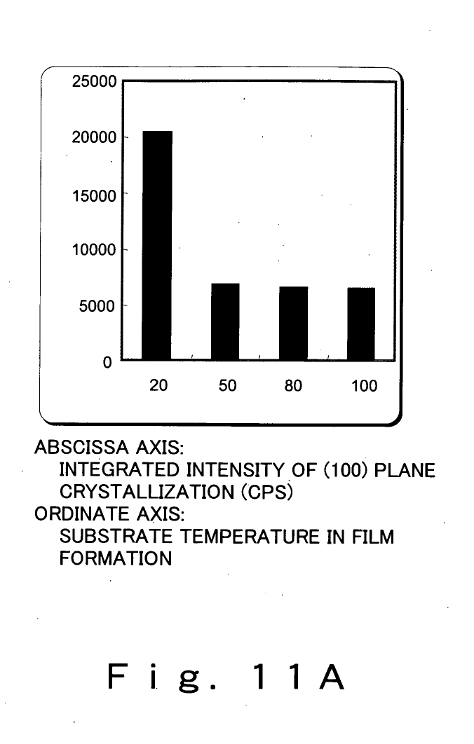

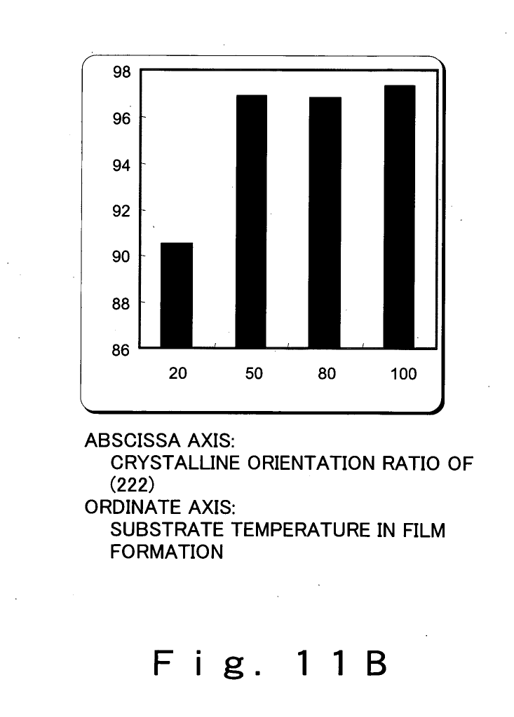

FIGS. 11A and 11B are graphs showing the dependence of crystalline orientation ratio of an integrated intensity of a (100) plane crystallization of the ferroelectric film 6 and a (222) plane on the electrostatic chuck temperature when the ferroelectric film 6 is formed. A (001) or (111) (or (222)) crystallization of the ferroelectric film 6 contributes to the switching characteristic of the ferroelectric capacitor 8. On the other hand, the (100) plane crystallization does not contribute to the switching characteristic of the ferroelectric capacitor 8. Accordingly, when the number of the (101) orientated crystallization or non-oriented crystallization is increased, the yield of the FeRAM device is deteriorated. It is defined that (the PZT (222) orientation ratio)=(the integrated intensity of PZT (222))*100/[(222)+(101)+(100) integrated intensity]. As shown in FIG. 11A, in a case where the substrate temperature is 20° C., the crystallization of CSPLZT is mainly (100) oriented. As shown in FIG. 11B, in a case where the substrate temperature is 50° C. to 100° C., the crystallization of CSPLZT is mainly (111) oriented. The orientation ratio of PZT (222) is equal to or more than 96%. As a result, in an initial stage of a CSPLZT target, in a case where the erosion is small and the substrate temperature is low, the energy applied to the sputtering atoms becomes too low, so the deposited amorphous film has no short-distance order property. On the other hand, within a range of the substrate temperature of 50° C. to 100° C., the energy is applied to the sputtering atoms to some extent, so the sputtering atoms deposited on the substrate are deposited in orderly alignment.

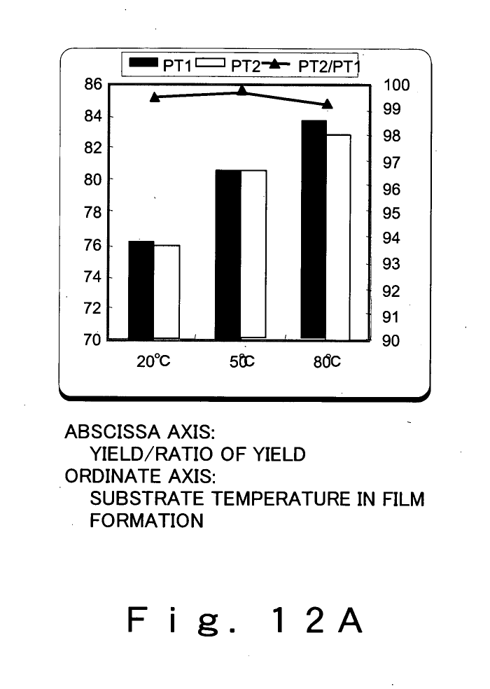

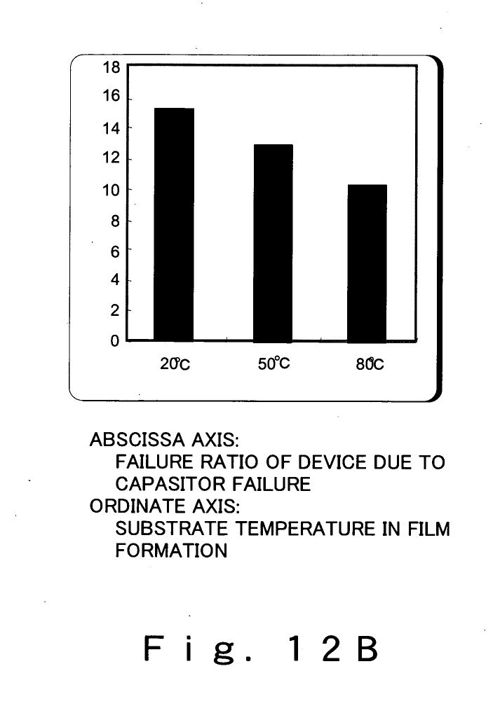

FIGS. 12A and 12B are graphs showing a ratio between the yield of the device manufactured by the method of Embodiment 1 and the ferroelectric failure. As shown in FIGS. 12A and 12B, the substrate temperature in the case of film formation affects a device yield of CSPLZT. When film formation is performed at the temperature of about 20° C., the crystallinity of the ferroelectric is deteriorated, and the yield is deteriorated by PT1. This is caused by a single bit failure of the ferroelectric capacitor due to the deterioration of the crystallinity of the ferroelectric film 6.

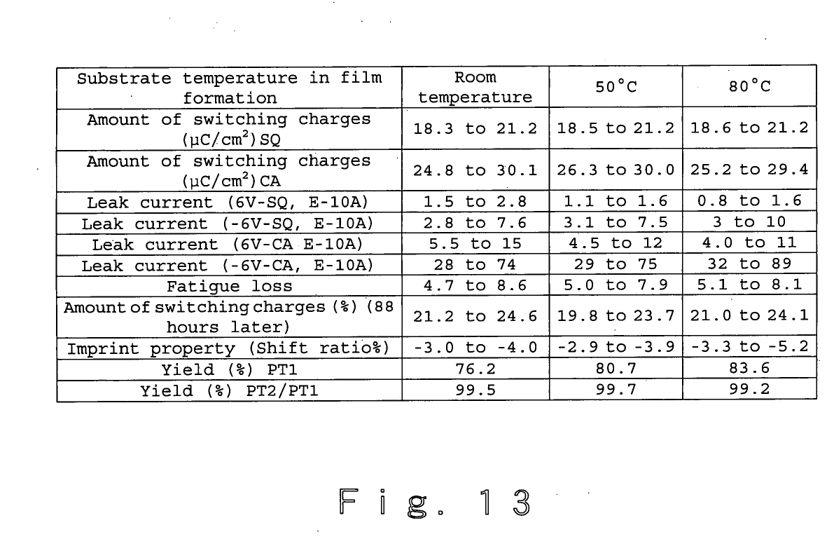

Table of FIG. 13 shows a result of the measured electric property of the ferroelectric capacitor manufactured by the above-mentioned method. By forming a ferroelectric capacitor (discrete, represented by SQ) whose planar shape is a square having a side of 50 μm, and 1428 ferroelectric capacitors (cell capacitor, represented by CA) whose planar shape is a rectangle having a long side of 1.50 μm and a short side of 1.15 μm, the amount of inversion charge quantity QSW (applied voltage of 3 V), a leak current (applied voltage of ±6 V), a fatigue loss of a cell array (acceleration of 7 V, measured voltage of 3 V), a retention property (Q2 (88)), and an imprint property (Q3 Rate) were measured. As apparent from the table, if the film-forming temperature is within a range of 20 to 80° C., the electric property of the capacitor is not greatly affected. However, the result shows an average amount of the cell arrays, so the failure of the single bit does not seem to appear in the measured data.

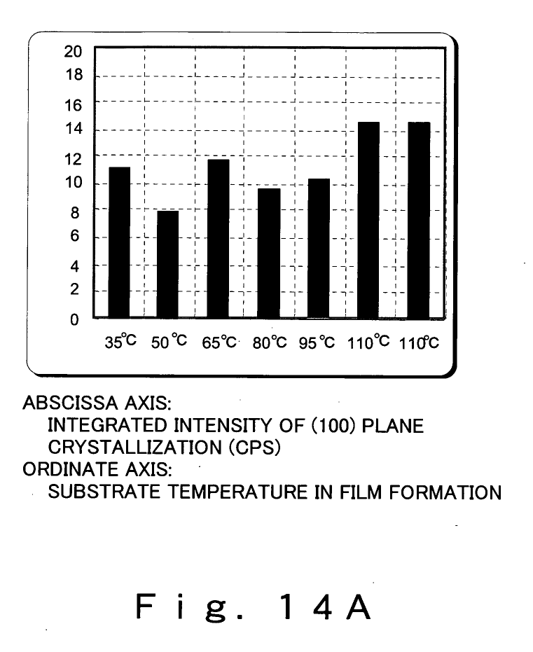

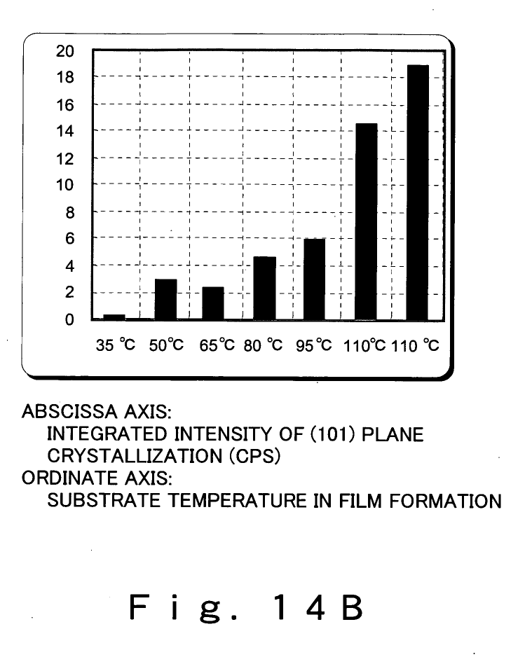

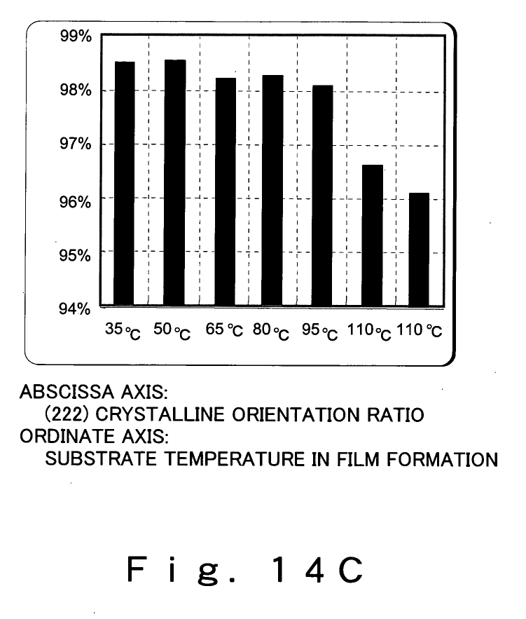

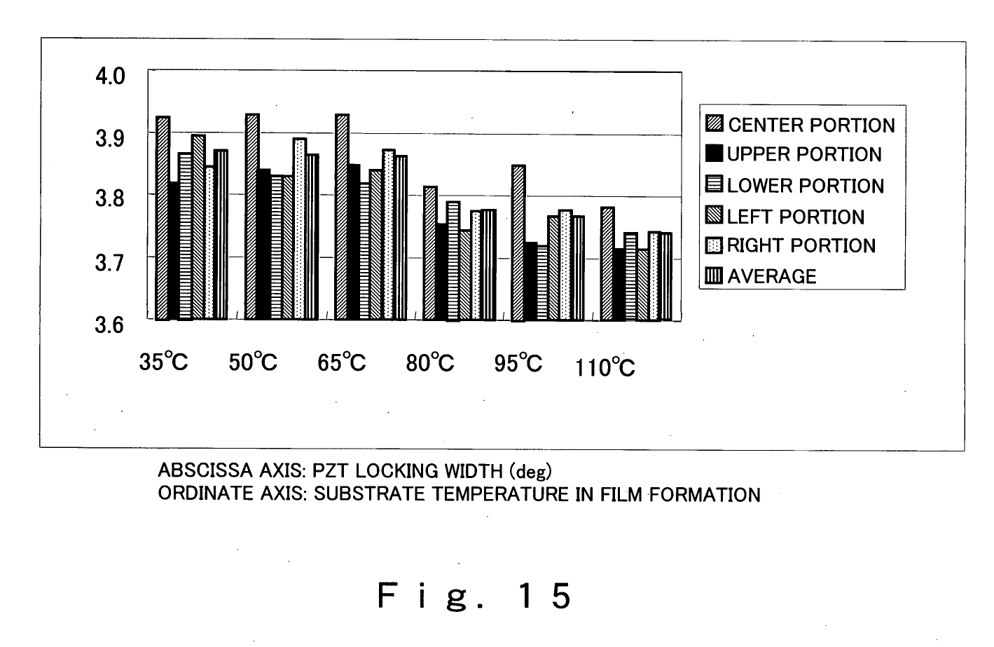

FIGS. 14A, 14B, and 14C show a dependence of the crystallinity of the ferroelectric film formed when the integral power consumption of the target is 520 kWh upon the film-forming temperature. As the erosion of the target enlarges, the sputtering particles deposited on the substrate are more likely to be disturbed. FIG. 15 shows an in-plane distribution of a half width of a CSPLZT (111) film measured by 4-axis XRD. When the substrate temperature is high, large energy is applied to the sputtering atoms, so the half width of the (111) surface of the CSPLZT film becomes narrower, thereby improving the in-plane distribution. However, large energy is applied, the short-distance order property of the amorphous film is deteriorated, thereby appearing a crystallized CSPLZT (101) orientation. As a result, it is apparent that the substrate temperature needs to be lowered as the erosion of the target develops.

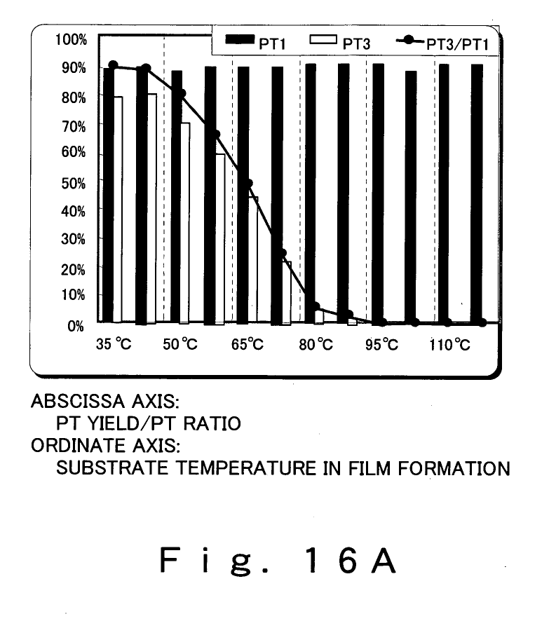

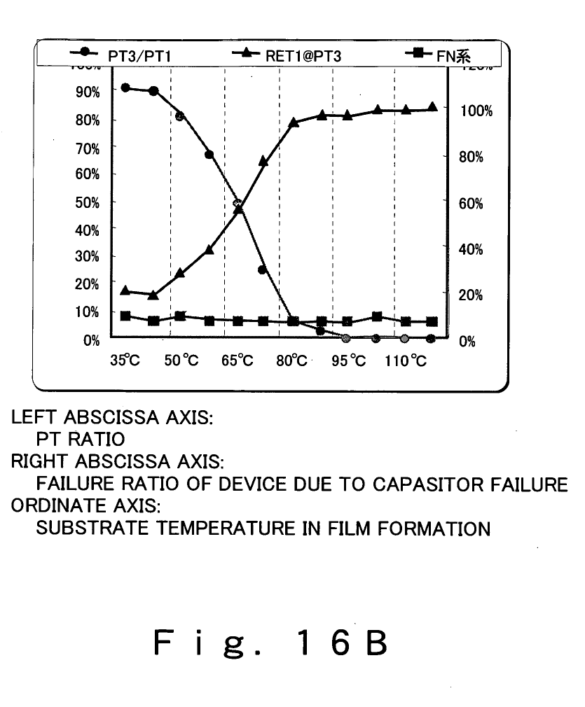

On the other hand, electric properties of the capacitor formed by the above-mentioned method are the same when the film-forming temperature is within 35 to 100° C., so the description thereof is omitted. FIG. 16A shows a PT yield of a 1T1C device and a PT ratio. FIG. 16B shows a PT ratio of the 1T1C device and a device yield fraction defective due to the failure of the ferroelectric capacitor. When the yield is measured, the operating voltage is set to 3 V. Reference symbol PT1 denotes a yield when reading is performed after writing is performed. Reference symbol PT2 denotes a yield when heat treatment is performed at the temperature of about 250° C. before reading is performed, and Reference symbol PT3 denotes a yield when data is reverted after heat treatment is performed with respect to PT2. The PT ratio is PT3/PT1. An FN system is a ratio of the yield due to the capacitor failure of the PT1. Reference symbol PET1@PT3 represents a ratio of a drop of the yield due to another capacitor failure. As shown in FIGS. 16A and 16B, when the film formation is performed at high temperature, it is apparent that the PT ratio is lowered to a large extent. It should be noted that the yield is determined based on the retention (SS: Same State failure) and the imprint (OS: Opposite State failure) of the ferroelectric film. In other words, when the film formation is performed at high temperature, the ferroelectric film 6 has more (101) orientated crystallization and non-orientated crystallization, thereby particularly affecting the single bit to cause the retention failure.

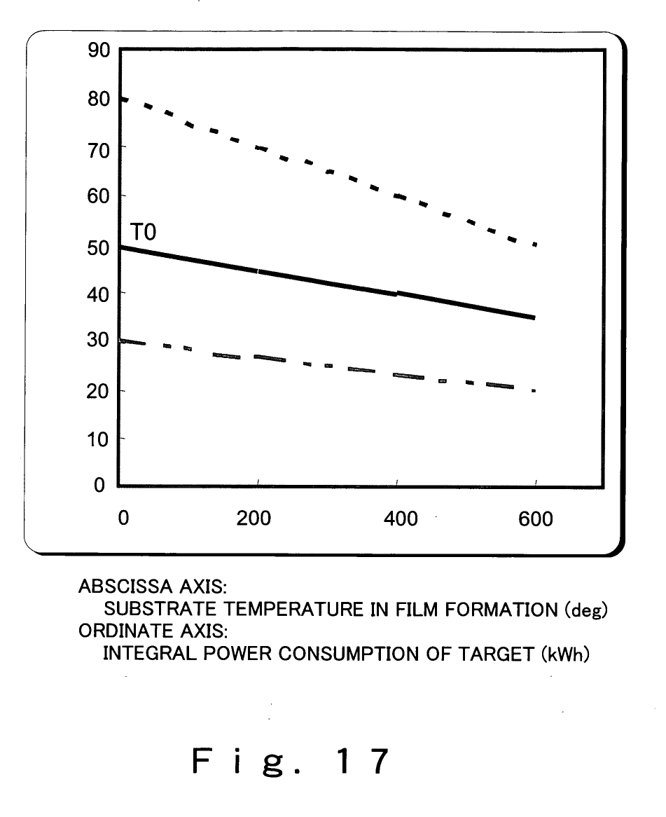

Furthermore, a test was performed to investigate the dependence of the integral power consumption of the target on the yield. The integral power consumption of the target and the film-forming temperature of the substrate affect the yield of the device. FIG. 17 is a graph showing a relationship between the optimum film-forming temperature for formation of the ferroelectric film 6 and the integral power consumption of the target. The optimum temperature for film formation when the target is not in use is represented by T0. The optimum temperature Ts for film formation is obtained by the following expression (1).

Ts=T0−a·L1·T0/L: Expression (1)

where, the initial set temperature is represented by T0 (° C.), the constant is represented by a, the available electric energy of the target is represented by L (kWh), the integral power consumption of the target is represented by L1, and reference symbol a denotes a constant (an upper and lower limit of the optimum temperature can be represented by the same expression, but the constant a changes to some extent).

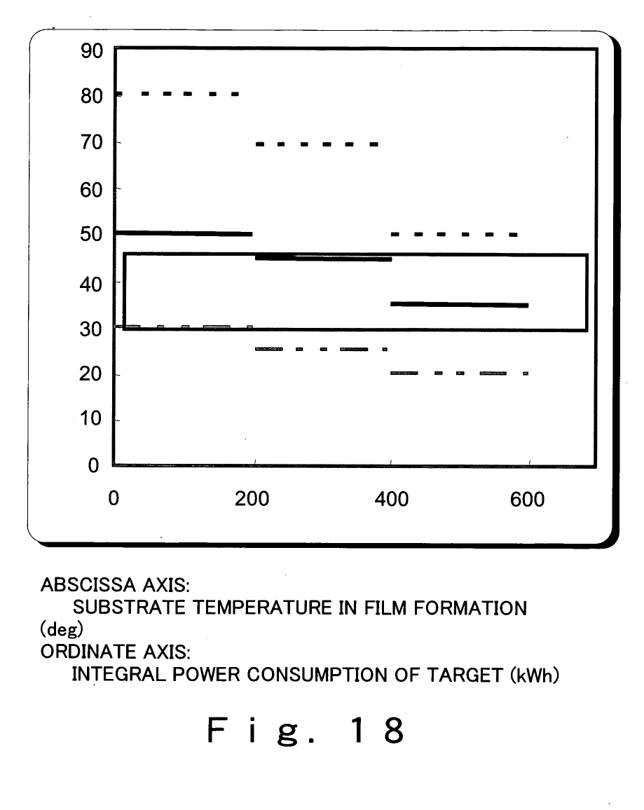

While, FIG. 18 is a graph showing a relationship between the integral power consumption of the target and the substrate temperature in a case where film formation is performed by a method in which the substrate temperature at the film formation is gradually lowered in accordance with the integral power consumption of the target in order to make it easy to operate mass production. The optimum temperature Ts for the film formation is represented by the following expression (1).

Ts=T0(initial set temperature)((target integration life)<(target available life)/n), T1((target integration life)<2·(target available life)/n), T2, T3, . . . , T(n−1), Tn((target integration life)<(n−1)·(target available life)/n): n is a natural number.

(This corresponds to Sequence (1): Ts=Tk(L1<L·(k+1)/(n+1)) where, k=0, 1, 2, . . . , n: the available electric energy of the target L (kWh) according to the present invention.)

In a case of the CSPLZT target, the optimum temperature for film formation is set as T0=50° C. (0 to 200 kWh), T1=45° C. (201 to 400 kWh), and T2=35° C. (401 to 600 kWh). Further, when the range of the optimum temperature is considered, the optimum temperature for film formation is 35° C.

As described above, according to the magnetron-sputtering film-forming apparatus and the manufacturing method for a semiconductor device of the present invention, the substrate temperature most suitable for sputtering based on an integral power consumption of a discharged electricity of a target is calculated, and the substrate temperature is adjusted to perform sputtering. Accordingly, the ferroelectric film to be deposited by the sputtering can be controlled in a state in which the short-distance order property is included, thereby making it possible to enhance the crystallinity of the crystallized ferroelectric film. In other words, it is possible to provide an FeRAM device with a high yield and high reliability.

In addition, the magnetron-sputtering film-forming apparatus and the manufacturing method for the semiconductor device according to the present invention includes matters regarding the following notes.

### <Others>

The disclosures of Japanese patent application No. JP2006-087957 filed on Mar. 28, 2006 including the specification, drawings and abstract are incorporated herein by reference.

What is claimed is:

1. A magnetron-sputtering film-forming apparatus, comprising:
a vacuum film-forming chamber forming a thin film on a substrate to be processed which is contained inside thereof;
electrostatic chuck units holding the substrate to be processed contained within the vacuum film-forming chamber by electrostatic adsorption, and adjusting a temperature Ts (° C.) of the substrate to be processed;
a target arranged to be opposed to the substrate to be processed which is held by the electrostatic chuck units, causing high-frequency magnetron sputtering to be performed on the substrate to be processed by discharging;
gas supplying units supplying discharge gas in the vacuum film-forming chamber, the gas supplying units being capable of adjusting a pressure within the vacuum film-forming chamber;
power supply units applying a discharge voltage between the substrate to be processed and the target, and calculating an integral power consumption L1 (kWh) of an electricity discharged by the target until that time;
control units controlling the electrostatic chuck units and the power supply units, in which the control units controls the electrostatic chuck units to adjust the temperature Ts of the substrate to be processed so that the following expression (1) is satisfied, and then applies the discharge voltage.
Ts=T0−a·L1·T0/L: Expression (1)
where, the initial set temperature is represented by T0 (° C.), a constant is represented by a, and the available electric energy of the target is represented by L (kWh).

2. A magnetron-sputtering film-forming apparatus, comprising:
A vacuum film-forming chamber forming a thin film on a substrate to be processed which is contained inside thereof;
electrostatic chuck units holding the substrate to be processed contained within the vacuum film-forming chamber by electrostatic adsorption, and adjusting a temperature Ts (° C.) of the substrate to be processed;
a target arranged to be opposed to the substrate to be processed which is held by the electrostatic chuck units, causing high-frequency magnetron sputtering to be performed on the substrate to be processed by discharging;
gas supplying units supplying discharge gas in the vacuum film-forming chamber, the gas supplying units being capable of adjusting a pressure within the vacuum film-forming chamber;
power supply units applying a discharge voltage between the substrate to be processed and the target, and calculating an integral power consumption L1 (kWh) of an electricity discharged by the target until that time;
control units controlling the electrostatic chuck units and the power supply units, in which the control units controls the electrostatic chuck units to adjust the temperature Ts of the substrate to be processed so that the following sequence (1) is satisfied, and then applies the discharge voltage.
Ts=Tk(L1<L·(k+1)/(n+1)) Sequence (1)
where, k=0, 1, 2, . . . , n: the available electric energy of the target L (kWh).

3. A magnetron-sputtering film-forming apparatus according to claim 2, in which the sequence (1) further satisfies the following sequence (1a).
T0≧T1≧ . . . ≧Tn. Sequence (1a)

4. A magnetron-sputtering film-forming apparatus according to claim 2, in which the sequence (1) further satisfies that the T0 is 30 to 80 when the L1 is 0 to 200, satisfies that the T1 is 25 to 75 when the L1 is 200 to 400, and satisfies that the T2 is 20 to 50 when the L2 is 400 to 600.

5. A magnetron-sputtering film-forming apparatus according to claim 2, in which the sequence (1) further satisfies n=0 and Ts=T0=about 35.

6. A magnetron-sputtering film-forming apparatus according to claim 1, in which the temperature Ts of the substrate to be processed further satisfies that the Ts is 20 to 100.

7. A magnetron-sputtering film-forming apparatus according to claim 1, in which the target has a perovskite structure expressed by a chemical formula ABO₃ (where, A is any one of Bi, Pb, Ba, Sr, Ca, Na, K, and rare earth elements, and B is any one of Ti, Zr, Nb, Ta, W, Mn, Fe, Co, and Cr).

8. A magnetron-sputtering film-forming apparatus according to claim 1, in which the target composed of a chemical formula Pb(Zr, Ti) O₃ or a dope Pb(Zr, Ti) O₃ composed of at least one element selected from the group consisting of Ca, Sr, La, and Ir.

9. A manufacturing method for a semiconductor device, comprising:
forming an insulating film on a semiconductor substrate;
forming a lower electrode adhesive layer on the insulating film;
forming a lower electrode having a (111) orientation on the lower electrode adhesive layer;
forming an amorphous ferroelectric layer on the lower electrode having a (111) orientation in a state in which the temperature of the semiconductor substrate is 20 to 100° C.;
thermally treating the amorphous ferroelectric layer in a mixed atmosphere of oxidized gas and inert gas;
forming an upper electrode on the amorphous ferroelectric layer.

10. A manufacturing method for a semiconductor device, comprising:
forming a semiconductor element on a semiconductor substrate;
forming an insulating film on the semiconductor substrate on which the semiconductor element is formed;
forming a contact hole reaching the semiconductor element on the insulating film;
forming a plug having a conductor film connected to the semiconductor element to be embedded in the contact hole;
forming a conductive hydrogen barrier layer, a conductive oxygen barrier layer, and a lower electrode on the insulating film to be in contact with the plug;
forming an amorphous ferroelectric layer on the lower electrode in a state in which the temperature of the semiconductor substrate is 20 to 100° C.;
thermally treating the amorphous ferroelectric layer in a mixed atmosphere of oxidized gas and inert gas;
forming an upper electrode on the amorphous ferroelectric layer.

11. A manufacturing method for a semiconductor device according to claim 9, in which the amorphous ferroelectric layer is formed in a state where the temperature of the semiconductor substrate is 20 to 50° C.

12. A manufacturing method for a semiconductor device according to claim 9, in which the amorphous ferroelectric layer is formed in a state where the temperature of the semiconductor substrate is about 35° C.

13. A manufacturing method for a semiconductor device according to claim 9, in which the lower electro adhesive layer is composed of at least one of an insulating adhesive film, a conductive adhesive film, a conductive hydrogen barrier film, and a conductive oxygen barrier film.

14. A manufacturing method for a semiconductor device according to claim 13, in which the lower electrode adhesive layer is composed of at least one material of aluminum oxide, aluminum nitride, tantalum oxide, titanium oxide, and zirconium oxide.

15. A manufacturing method for a semiconductor device according to claim 13, in which the lower electrode adhesive layer is composed of at least one of a TiN film, a TiAlN film, an Ir film, an IrOx film, a Pt film, an Ru film, an RuOx film, an Os film, and a Ta film.

16. A manufacturing method for a semiconductor device according to claim 13, in which the conductive hydrogen barrier film is composed of a TiAlN film, a TiAlON film, a TiN/TiAlN laminated film, a TaN/TiAlN laminated film, or an alloy film composed of Ti, Ta, TiN, TaN, TiAlN, or TiAlON.

17. A manufacturing method for a semiconductor device according to claim 13, in which the conductive oxygen barrier film is composed of a TiAlN film, a TiAlON film, a TiN/TiAlN laminated film, a TaN/TiAlN laminated film, an Ir film, an Ru film, or an alloy film composed of Ti, Ta, TiN, TaN, TiAlN, TiAlON, Ir, or Ru.

18. A manufacturing method for a semiconductor device according to claim 9, in which the lower electrode is composed of at least one material of Pt, Ir, Ru, Rh, Re, Os, Pd, or an oxide thereof, and SrRuO₃.

19. A manufacturing method for a semiconductor device according to claim 9, in which the upper electrode is composed of at least one material of Ir, Ru, Rh, Re, Os, Pd, or an oxide thereof, and SrRuO₃.

20. A manufacturing method for a semiconductor device according to claim 9, in which the oxidized gas contains oxygen.

21. A manufacturing method for a semiconductor device according to claim 9 for forming a thin film on a substrate to be processed by:
a vacuum film-forming chamber forming a thin film on a substrate to be processed contained therein;
electrostatic chuck units holding the substrate to be processed contained within the vacuum film-forming chamber by electrostatic adsorption, and adjusting a temperature Ts (° C.) of the substrate to be processed;
a target arranged to be opposed to the substrate to be processed which is held by the electrostatic chuck units, causing high-frequency magnetron sputtering to be performed on the substrate to be processed by discharging;
gas supplying units capable of adjusting the pressure within the vacuum film-forming chamber, supplying discharge gas to the vacuum film-forming chamber;
power supply units applying a discharge voltage between the substrate to be processed and the target, and calculating an integral power consumption L1 (kWh) of an electricity which is discharged by the target until that time;
control units controlling the electrostatic chuck units and the power supply units, in which the control units controls the electrostatic chuck units to adjust the temperature Ts of the substrate to be processed so that the following expression (1) is satisfied, and controls the power supply units to apply the discharge voltage.
Ts=T0−a·L1·T0/L: Expression (1)
where, the initial set temperature is represented by T0 (° C.), a constant is represented by a, and the available electric energy of the target is represented by L (kWh).

22. A manufacturing method for a semiconductor device according to claim 9 for forming a thin film on a substrate to be processed by:
a vacuum film-forming chamber forming a thin film on a substrate to be processed contained therein;
electrostatic chuck units holding the substrate to be processed contained within the vacuum film-forming chamber by electrostatic adsorption, and adjusting a temperature Ts (° C.) of the substrate to be processed;
a target arranged to be opposed to the substrate to be processed which is held by the electrostatic chuck units, causing high-frequency magnetron sputtering to be performed on the substrate to be processed by discharging;
gas supplying units capable of adjusting the pressure within the vacuum film-forming chamber, supplying discharge gas to the vacuum film-forming chamber;
power supply units applying a discharge voltage between the substrate to be processed and the target, and calculating an integral power consumption L1 (kWh) of an electricity which is discharged by the target until that time;
control units controlling the electrostatic chuck units and the power supply units, in which the control units controls the electrostatic chuck units to adjust the temperature Ts of the substrate to be processed so that the following sequence (1) is satisfied, and controls the power supply units to apply the discharge voltage.
Ts=Tk(L1<L·(k+1)/(n+1)) Sequence (1)
where, k=0, 1, 2, . . . , n: the available electric energy of the target L (kWh).
